(19) United States
(12) Patent Application Publication
(10) Pub. No.: US 2005/0063147 A1
(43) Pub. Date: Mar. 24, 2005

(54) Installation arrangement for computer system

(76) Inventor: Yun-Ping Yu, San Chung City (TW)

Correspondence Address: Raymond Y. Chan, Suite 128, 108 N. Ynez Ave., Monterey Park, CA, 91754, US

(21) Appl. No.: 10/900,412

(22) Filed: Jul. 26, 2004

(30) Foreign Application Priority Data
Jul. 28, 2003 (TW) 92213700

(51) Int. Cl. H05K 5/00

(52) U.S. Cl. 361/683

(57) ABSTRACT

An installation arrangement for a computer system includes a supporting platform and a guiding joint. The supporting platform has an upper and a lower compartment for receiving two memory devices therein respectively. The guiding joint has a joint body having an elongated guiding slot adapted for securely mounting at a sidewall of the main casing, and a lifting arm having a pivot end pivotally mounted to the supporting platform, and a guiding end slidably mounted to the joint body along the guiding slot to guide the supporting platform between an operation position and an installation position.

### BACKGROUND OF THE PRESENT INVENTION

1. Field of Invention

The present invention relates to a computer system, and more particularly to an installation arrangement for a computer system which allows easy and convenient replacement or assembling of peripheral hardware (e.g. CD-ROM drive) to a main casing.

2. Description of Related Arts

A conventional computer system usually comprises a display unit, a main casing having a supporting platform provided therein, a motherboard disposed in the main casing, a Central Processor electrically mounted on the motherboard, a plurality of computing cards electrically plugged to the motherboards for performing different computing functions, and a plurality of memory devices (such as hard-drive and CD Rom drive etc.) securely mounted in the supporting platform and electrically connected with the motherboard to provide memory storage for the computer system.

The supporting platform usually has a plurality of receiving compartments wherein the above-mentioned memory devices, such as hard drive, CD Rom, floppy drive etc. are arranged to securely mount in the corresponding receiving compartment so as to achieve a stable and secure structure of the computer system.

However, one should be aware that in light of the current rapid advancement of information technology, an installed hard drive, CD Rom, floppy drive etc. would become outdated very soon, and a user of the computer system would normally prefer to replace some more sophisticated and up-to-date memory drives, such as a faster and larger capacity hard drive, instead of replacing the computer system as a whole.

For non-professional users, this inevitably presents a great hassle because he/she needs to take out the relevant memory device from the main casing and then assemble a new one thereto. Where the outdated memory device is situated at the bottom compartment of the supporting platform, the user has no choice but to take out all the memory devices one by one and then reassemble and install them again. As he/she is not a professional mechanics, during the process of replacement and disassembling or assembling, some components, especially those extra small screws, would be lost very easily. Furthermore, the memory devices may be replaced improperly due to complicated connections in a rather confined space. Then, the ‘new’ system, which is originally intended to be faster or more effective, would in fact become more unstable and even more insecure. Subsequent transportation of which may even cause damage to the components inside the main casing.

Thus, in short, the conventional installation procedures and arrangement for computer systems are of great hassle, time-consuming, as well as unsatisfactory in general.

### SUMMARY OF THE PRESENT INVENTION

A main object of the present invention is to provide an installation arrangement for a computer system which allows easy and convenient replacement or assembling of peripheral hardware, such as a memory device, to a main casing.

Another object of the present invention is to provide an installation arrangement for a computer system which comprises a guiding joint mounted in a main casing of the computer system for lifting up a supporting platform in a rotatably flippable manner so that the memory devices stored in the supporting platform can be conveniently accessed by the user for replacement or upgrade.

Another object of the present invention is to provide an installation arrangement for a computer system which is simple in structure so as not to cause significant interference with other devices inside the main casing, and to minimize the manufacturing cost of the present invention.

Accordingly, in order to accomplish the above objects, the present invention provides an installation arrangement for a computer system comprising a main casing, comprising:

a supporting platform having an upper and a lower compartment for receiving two memory devices therein respectively; and

a guiding joint comprising a joint body having an elongated guiding slot adapted for securely mounting at a sidewall of the main casing, and a lifting arm having a pivot end pivotally mounted to the supporting platform and a guiding end slidably mounted to the joint body along the guiding slot to guide the supporting platform between an operation position and an installation position, wherein at the operation position, the guiding end of the lifting arm is slid to one end of the guiding slot to pivotally fold the supporting platform to rest within the main casing, and at the installation position, the guiding end of the lifting arm is slid to an opposed end of the guiding slot to elevate the supporting platform from the main casing, thereby a user is able to assemble the memory device at the lower compartment without detaching the another memory device at the upper compartment.

These and other objectives, features, and advantages of the present invention will become apparent from the following detailed description, the accompanying drawings, and the appended claims.

### BRIEF DESCRIPTION OF THE DRAWINGS

FIG. 1 is perspective view of an installation arrangement for a computer system according to a preferred embodiment of the present invention.

FIG. 2 is an exploded perspective view of the installation arrangement for the computer system according to the above preferred embodiment of the present invention.

FIG. 3 is a perspective schematic view of the installation arrangement for according to the above preferred embodiment of the present invention, illustrating that a memory device is about to install into a particular compartment.

FIG. 4 is a perspective schematic view of the installation arrangement according to the above preferred embodiment of the present invention, illustrating that a memory device has been installed into a particular compartment.

FIG. 5 is a perspective schematic view of the installation arrangement according to the above preferred embodiment of the present invention, illustrating that the supporting platform is in the installation position.

FIG. 6 is a side view of the installation arrangement according to the above preferred embodiment of the present invention, illustrating that the supporting platform is in the installation position.

FIG. 7 is a perspective schematic diagram of the installation arrangement according to the above preferred embodiment of the present invention, illustrating that the supporting platform is flipping over about the lifting arm.

FIG. 8 is a perspective schematic diagram of the installation arrangement according to the above preferred embodiment of the present invention, illustrating that the supporting platform has been flipped over about the lifting arm.

FIG. 9 is a side view of the installation arrangement according to the above preferred embodiment of the present invention, illustrating that the supporting platform is flipped over.

FIG. 10 is a perspective schematic diagram of the installation arrangement according to the above preferred embodiment of the present invention, illustrating that the lower compartment is flipped over to be installed with a memory device.

FIG. 11 is a perspective view of the installation arrangement according to the above preferred embodiment of the present invention, illustrating that the memory device is installed in the lower compartment.

### DETAILED DESCRIPTION OF THE PREFERRED EMBODIMENT

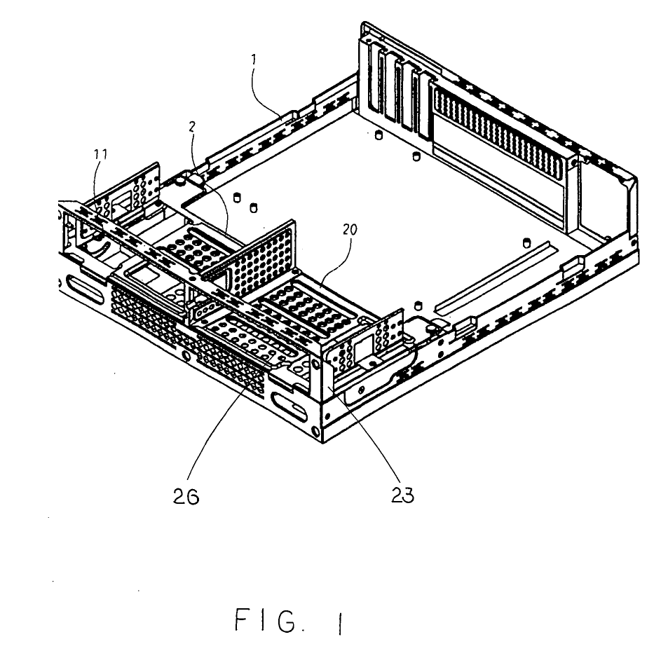

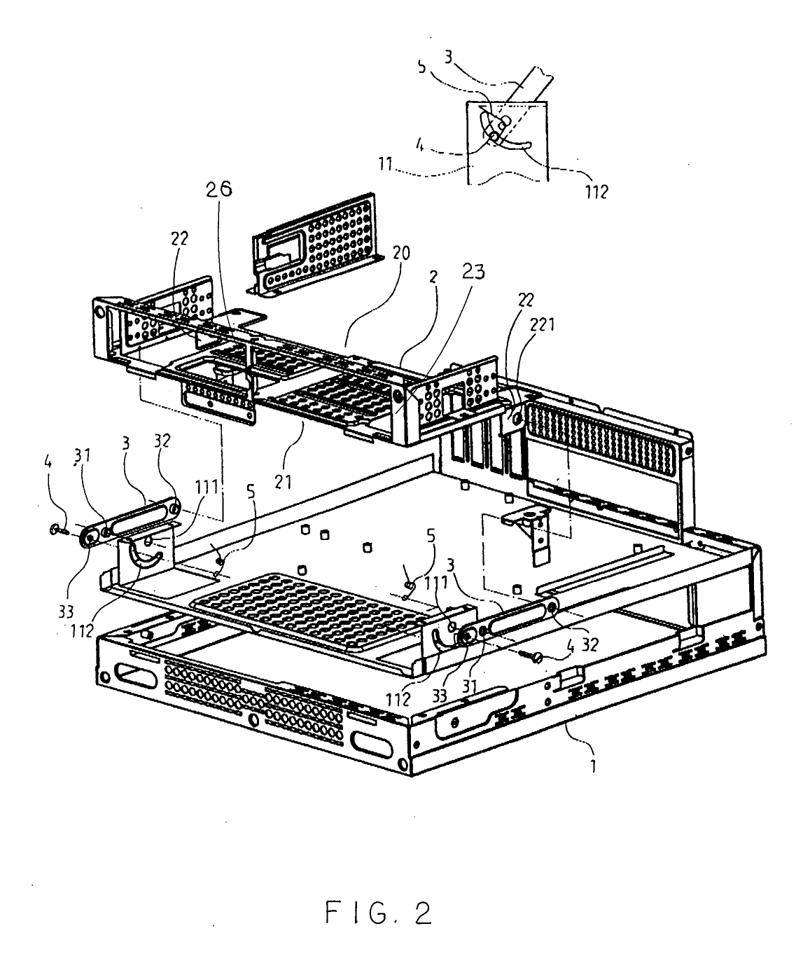

Referring to FIG. 1 and FIG. 2 of the drawings, an installation arrangement for a computer system according to a preferred embodiment of the present invention is illustrated, in which the installation arrangement comprises a supporting platform 2 and two guiding joints. The computer system is embodied as a conventional computer system comprising a main casing 1, a motherboard disposed in the main casing, a central processor electrically mounted to the motherboard, a plurality of computing cards electrically plugged on the motherboard, and a plurality of memory devices (6,7,8) (such as hard-drive, CD-Rom drive etc.) mounted to the supporting platform 2.

The supporting platform 2 has an upper compartment 20 and a lower compartment 21 for receiving two memory devices 6, 7, 8 therein respectively. Each of the guiding joints comprises a joint body 11 having an elongated guiding slot 112 adapted for securely mounting at a sidewall of the main casing 1, and a lifting arm 3 having a pivot end 32 pivotally mounted, through a mounting screw 4, to the supporting platform 2, and a guiding end 33 slidably mounted to the joint body 11 along the guiding slot 112 to guide the supporting platform 2 moving between an operation position and an installation position, wherein in the operation position, the guiding end 33 of the lifting arm 3 is slid to a first stopping end of the guiding slot 112 to pivotally fold the supporting platform 2 to rest within the main casing 1, wherein in the installation position, the guiding end 33 of the lifting arm is slid along the guiding slot 221 to a second opposed stopping end thereof to elevate the supporting platform 2 from the with respect to the main casing 1. As a result, a user is able to assemble the memory device 6, 7, 8 at the lower compartment 21 without detaching another memory device 6, 7, 8 in the upper compartment 20 of the supporting platform 2.

According to the preferred embodiment, the supporting platform 2 comprises a supporting base 26 wherein the upper compartment 20 is formed above the supporting base 26, and the lower compartment 21 is formed below the supporting base 26 such that when the supporting platform 2 is flipped upside down in the installation position, the lower compartment 21 is positioned above the upper compartment 20.

The guiding slot 112 has a predetermined radius of curvature that the guiding end 33 of the lifting arm 3 is guided to slide along the guiding slot 112 to fold the lifting arm 3 with respect to the joint body 11 in accordance with a locus of the guiding slot 112 so as to upwardly, frontwardly, and suspendedly elevate the supporting platform 2 with respect to the main casing 1 at the installation position.

Referring to FIG. 2 of the drawings, the installation arrangement further comprising a pivot joint pivotally connecting the lifting arm 2 with the joint body 11, wherein the pivot joint is positioned at a center of the locus of the guiding slot 112 such that when the lifting arm 3 is pivotally moved with respect to the joint body 11, the guiding end 33 of the lifting arm 3 is guided to slide along the guiding slot 112 to move the supporting platform 2 between the operation position and the installation position. Accordingly, the pivot joint has a securing hole 31 formed on the lifting arm 3 between the guiding end 33 and the pivot end 32 and a locating hole 111 formed on the joint body 11 at the center of the locus of the guiding slot 112 to align with the securing hole 31 wherein a coupler, such as a rivet, is extended through the securing hole 31 and the locating hole 111 to pivotally connect the lifting arm 3 with the joint body 11.

In other words, the guiding end 33 of the lifting arm 3 is pivotally moved along the guiding slot 112 so as to drive the supporting platform 2 moving between the installation position and the operation position. The movement of the lifting arm 3 is therefore substantially guided by the locus of the elongated guiding slot 112.

The guiding joint further comprises means for guiding the supporting platform 2 moving between the installation position and the operation position. According to the preferred embodiment, the guiding means is preferably embodied as a guiding screw pivotally mounting the lifting arm 3 to the joint body 11 so that the guiding screw is arranged to block a further movement of the lifting arm 3 when it reaches either of two ends of the guiding slot 112. Of course, other obvious alternatives may also be employed in order to achieve substantially the same function. However, it is worth pointing out that the guiding screw is embodied as the above-mentioned mounting screw 4 for both retaining the supporting platform as well as pivotally mounting the lifting arm 3 with the flipping hinges 22 of the supporting platform 2.

Moreover, the supporting platform 2 further has a front installation opening communicating with the upper compartment 20 thereof so that when the supporting platform 2 is in the operation position, the front installation opening is substantially aligned with a front opening of the main casing 1 so as to communicate the front opening of the main casing 1 with the upper compartment 20. In other words, a user of the present invention is able to access to a memory device 6, 7, 8 to the upper compartment 20 via the front installation opening of the supporting platform and the front opening of the main casing even when the supporting platform 2 is in the operation position.

The joint body 11 has a rectangular shape and a top ceiling transversely extended therefrom to form a retraction surface. The guiding joint further comprises a resilient coil 5 having one end connected to the guiding end 33 of the lifting arm 3 and another end biasing against the top ceiling of the joint body 11. Accordingly, when the lifting arm 3 is pivotally moved to drive the supporting platform 2 moving from the operation position to the installation position, the guiding end 33 moves along the guiding slot 112 and the resilient coil 5 is elastically stretched. In other words, the resilient coil 5 normally exerts a retraction force which helps in restoring the supporting platform 2 moving back to the operation position. When the supporting platform 2 is in the installation position, due to the radius of curvature of the guiding slot 112, the supporting platform 2 is geometrically retained in the installation position. When the user wishes to return it to the operation position, he/she may simply slightly push the supporting platform 2 so that the lifting arm 3 is slightly pushed back along the guiding slot 112, the resilient coil 5 would then steadily return the supporting platform 2 back to the operation position.

The supporting platform 2 further comprises two flipping hinges 22 provided at two rear bottom portions of the supporting platform 2 respectively, and integrally and downwardly extended to pivotally connect with the respective pivot end 32 of the respective lifting arm 3 through a respective pivot hole 221.

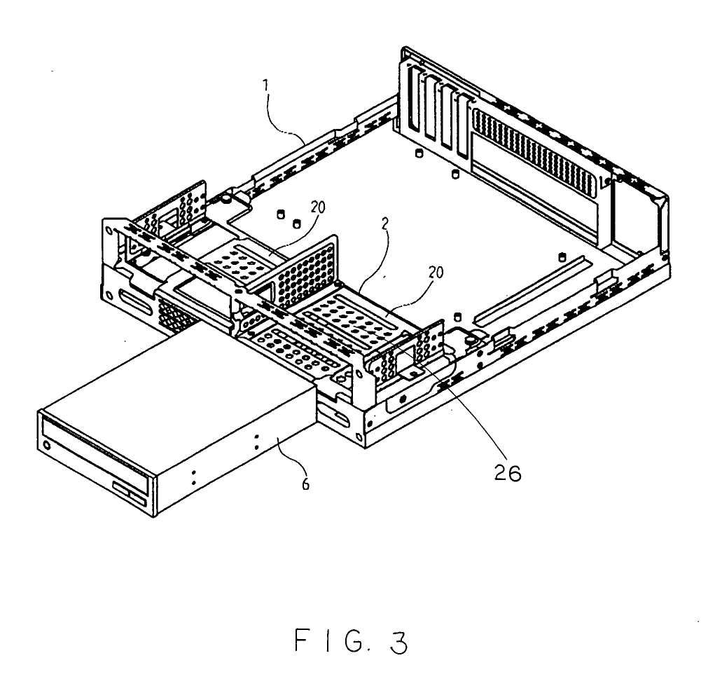

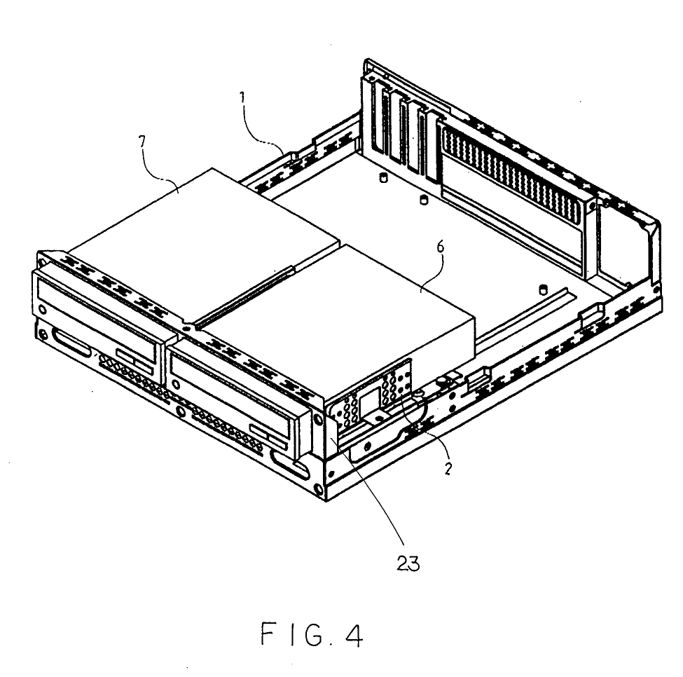

Referring to FIG. 3 to FIG. 4 of the drawings, when the supporting platform 2 is in the operation position, the supporting platform 2 rests in the main casing 1 and is substantially aligned with the front opening thereof so that the memory device 6, 7, 8, such as a CD-Rom drive, is able to be conveniently installed into the corresponding compartment 20, 21, as shown in FIG. 4 of the drawings.

The supporting platform 2 may further comprise a storage partition formed on the upper compartment 20 so as to isolate the upper compartment 20 into two sub-compartments adjacent to each other. Thus, two memory devices 6, 7, 8 may be installed into the respective sub-compartment wherein the two sub-compartments are substantially aligned with the respective front openings of the main casing 1 so that a user is able to control the relevant memory device 6, 7, 8 through the respective operation slot.

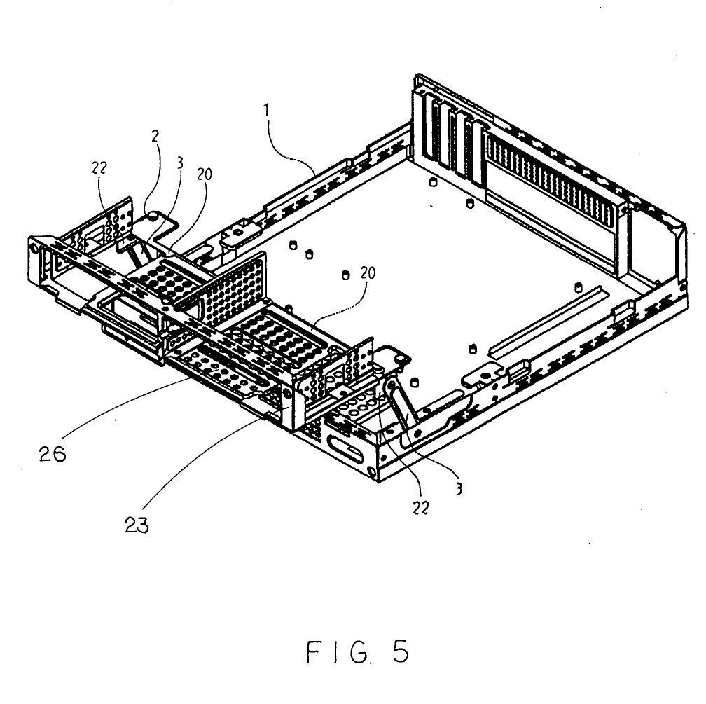

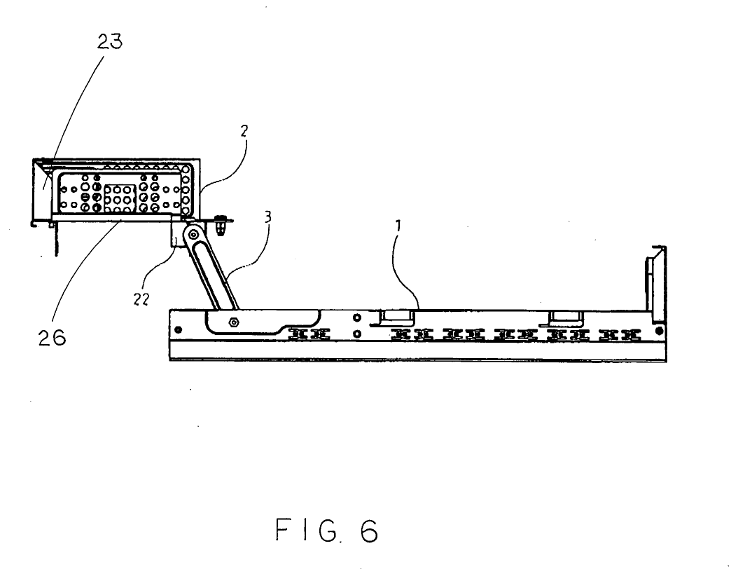

Referring to FIG. 5 to FIG. 6 of the drawings, when the supporting platform 2 is in the installation position, it is upwardly, frontwardly and suspendedly elevated with respect to the main casing 1 wherein the extent to which the supporting platform 2 can be elevated is substantially restrained by a length and a radius of curvature of the elongated guiding slot 112 formed on the joint body 11. Thus, it is important to realize that a vertical distance between the first and the second stopping end of the elongated guiding slot 112 equals the maximum possible vertical distance by which the supporting platform 2 can be elevated. Similarly, a horizontal distance between the first and the second stopping end of the elongated guiding slot 112 substantially determines the maximum possible distance by which the supporting platform 2 can be moved forwardly with respect to the main casing 1 so as to arrive to the installation position. In other words, the guiding end 33 of the lifting arm 3 is blocked at the first end of the guiding slot 112 to pivotally fold the supporting platform 2 to rest within the main casing 1 and is blocked at the second end to elevate the supporting platform 2 from the main casing 1.

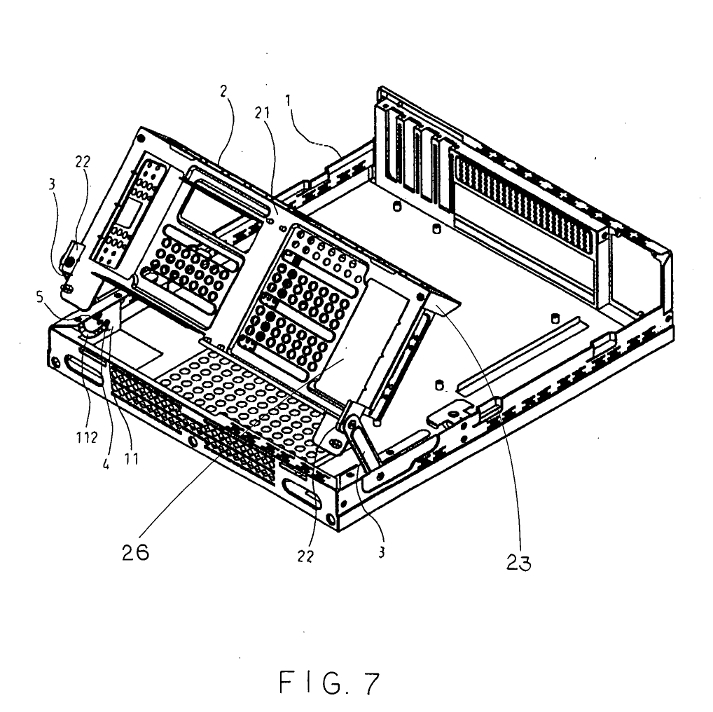

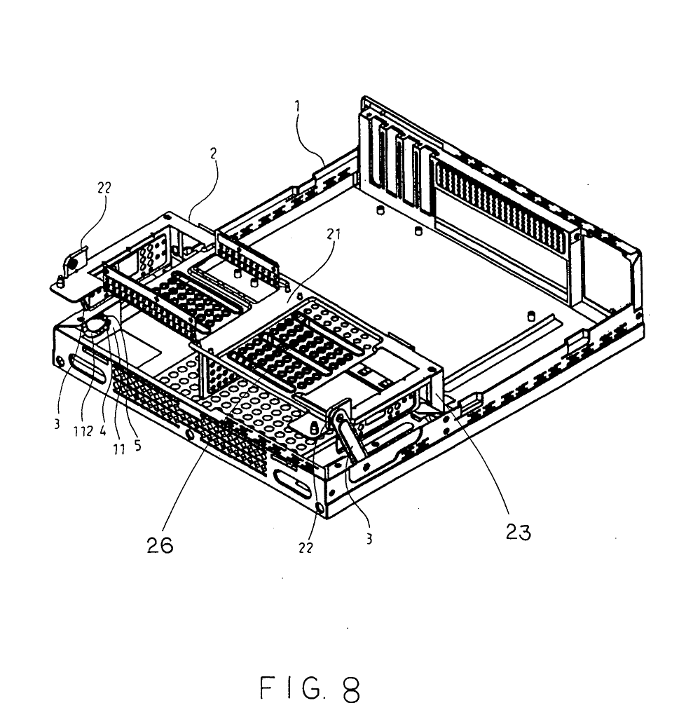

Referring to FIG. 7 to FIG. 8 of the drawings, the pivot ends 32 of the lifting arms 22 are rotatably mounted with the flipping hinges 22 of the supporting platform 2 in such a manner that it is capable of rotating about the pivot end 32 of the lifting arm 3 so as to inwardly flip over at 180° towards the main casing 1 so as to interchange a vertical position of the upper and the lower compartment 21 of the supporting platform 2.

As a result, the memory device (6,7,8), such as a hard disk, which is originally installed in the lower compartment 21 of the supporting platform 2 is flipped over and exposed upfront to the user of the present invention for convenient replacement or updating, as shown in FIG. 8 of the drawings.

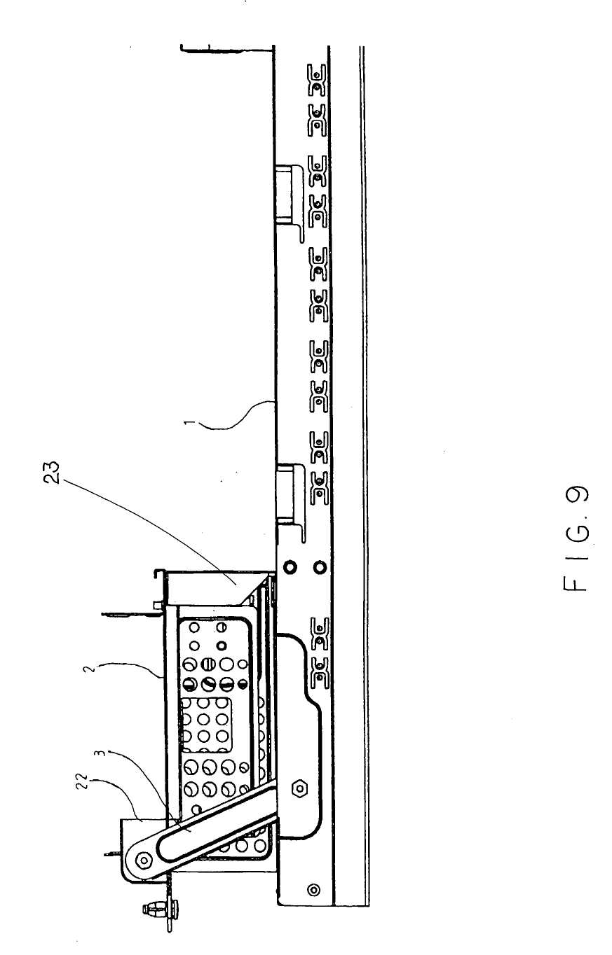

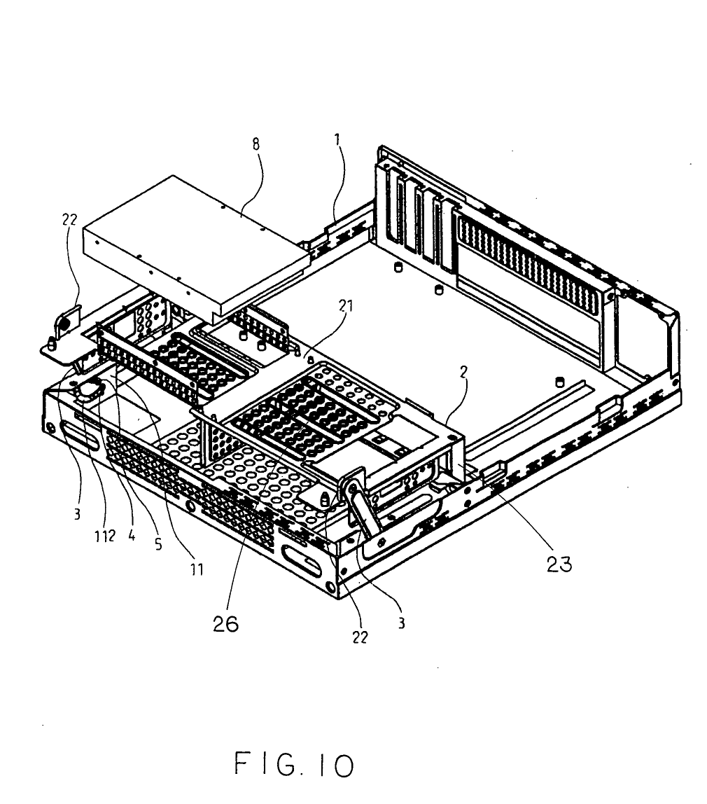

Referring to FIG. 9 to FIG. 10 of the drawings, when the vertical position of the upper compartment 20 and lower compartment 21 is interchanged, i.e. the upper compartment 20 is positioned below the lower compartment 21 after over-flipping in an upside down manner, a user is able to access to the lower compartment 21 very easily for replacement or installation of the memory devices 6, 7, 8. Moreover, the flipping movement also causes a position interchange between a front and a rear side of the supporting platform 2. Thus, a rear side of the corresponding memory device 6, 7, 8, where signal inlets are usually provided thereon, is flipped to expose to a front side with respect to the main casing 1 so that a user is able to easily connect/disconnect the memory device 6, 7, 8 with the motherboard from the front so as to install/replace the memory device 6, 7, 8 in question.

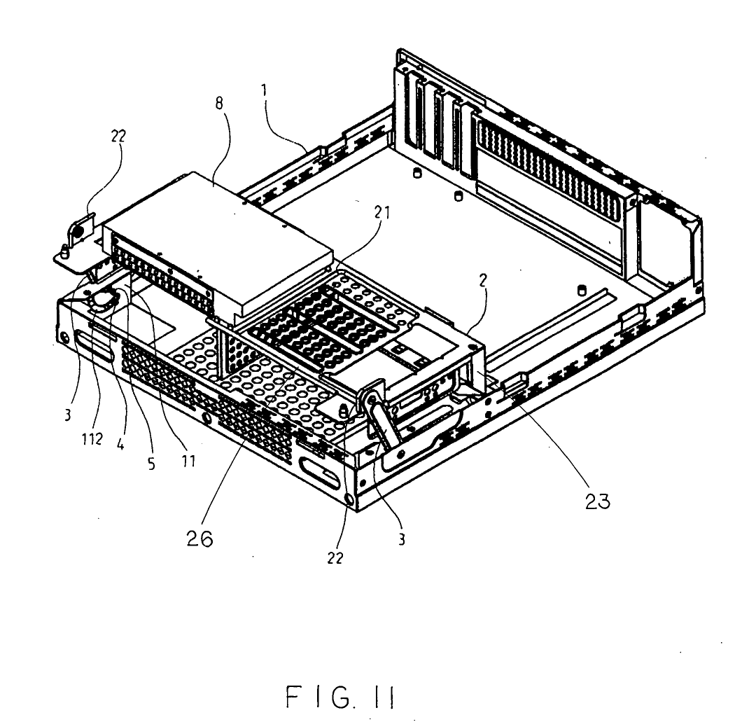

Referring to FIG. 6, FIG. 7 and FIG. 11 of the drawings, the supporting platform 2 further has two standing legs 23 upwardly and integrally extended from two front side portions thereof in such a manner that when the supporting platform 2 is inwardly flipped so as to interchange a position of the upper compartment 20 and the lower compartment 21, the two standing legs 23 are adapted to engage and stand on the main casing 1 so as to retain the supporting platform 2 in position with respect to the main casing 1. Thus, user of the present invention is able to perform installation or replacement of memory devices 6, 7, 8, such as a hard-drive, with maximum convenience, stability, and flexibility.

Obviously, after the user has installed an updated memory device (6,7,8) in the relevant compartment 20, 21, he/she may flip the supporting platform 2 back to its original position (i.e. installation position), and if everything is done, the user may pivotally move the supporting platform 2 back to the operation position with the help of the resilient coil 5.

To conclude, the forgoing description substantially the above-mentioned objects of the present invention.

One skilled in the art will understand that the embodiment of the present invention as shown in the drawings and described above is exemplary only and not intended to be limiting.

It will thus be seen that the objects of the present invention have been fully and effectively accomplished. It embodiments have been shown and described for the purposes of illustrating the functional and structural principles of the present invention and is subject to change without departure from such principles. Therefore, this invention includes all modifications encompassed within the spirit and scope of the following claims.

1. An installation arrangement for a computer system comprising a main casing, comprising:
a supporting platform having an upper and a lower compartment for receiving two memory devices therein respectively; and
at least one guiding joint comprising a joint body having an elongated guiding slot adapted for securely mounting at a sidewall of said main casing, and a lifting arm having a pivot end pivotally mounted to said supporting platform and a guiding end slidably mounted to said joint body along said guiding slot to guide said supporting platform between an operation position and an installation position, wherein at said operation position, said guiding end of said lifting arm is slid to a first end of said guiding slot to pivotally fold said supporting platform to rest within said main casing, and at said installation position, said guiding end of said lifting arm is slid to an opposed second end of said guiding slot to elevate said supporting platform from said main casing, thereby a user is able to assemble said memory device at said lower compartment without detaching said another memory device at said upper compartment.

2. The installation arrangement, as recited in claim 1, wherein said supporting platform further comprises at least a flipping hinge provided at a rear bottom portion of said supporting platform to pivotally connect with said pivot end of said lifting arm such that said supporting platform is adapted to flip over about said pivot end in an upside down manner to switch said upper compartment at a position below said lower compartment.

3. The installation arrangement, as recited in claim 1, wherein said guiding slot has a predetermined radius of curvature that said guiding end of said lifting arm is guided to slide along said guiding slot to pivotally fold said lifting arm with respect to said joint body in accordance with a locus of said guiding slot so as to upwardly, frontwardly, and suspendedly elevate said supporting platform with respect to said main casing at said installation position.

4. The installation arrangement, as recited in claim 2, wherein said guiding slot has a predetermined radius of curvature that said guiding end of said lifting arm is guided to slide along said guiding slot to fold said lifting arm with respect to said joint body in accordance with a locus of said guiding slot so as to upwardly, frontwardly, and suspendedly elevate said supporting platform with respect to said main casing at said installation position.

5. The installation arrangement, as recited in claim 3, further comprising a pivot joint pivotally connecting said lifting arm with said joint body, wherein said pivot joint is positioned at a center of said locus of said guiding slot such that when said lifting arm is pivotally moved with respect to said joint body, said guiding end of said lifting arm is guided to slide along said guiding slot to move said supporting platform between said operation position and said installation position.

6. The installation arrangement, as recited in claim 4, further comprising a pivot joint pivotally connecting said lifting arm with said joint body, wherein said pivot joint is positioned at a center of said locus of said guiding slot such that when said lifting arm is pivotally moved with respect to said joint body, said guiding end of said lifting arm is guided to slide along said guiding slot to move said supporting platform between said operation position and said installation position.

7. The installation arrangement, as recited in claim 4, wherein a vertical height of said guiding slot is a maximum distance to which said supporting platform is elevated, and a horizontal length of said guiding slot is a maximum distance to which said supporting platform is frontwardly moved to reach said installation position from said operation position such that said guiding end of said lifting arm is blocked at said first end of said guiding slot to pivotally fold said supporting platform to rest within said main casing and is blocked at said second end to elevate said supporting platform from said main casing.

8. The installation arrangement, as recited in claim 6, wherein a vertical height of said guiding slot is a maximum distance to which said supporting platform is elevated, and a horizontal length of said guiding slot is a maximum distance to which said supporting platform is frontwardly moved to reach said installation position from said operation position such that said guiding end of said lifting arm is blocked at said first end of said guiding slot to pivotally fold said supporting platform to rest within said main casing and is blocked at said second end to elevate said supporting platform from said main casing.

9. The installation arrangement, as recited in claim 2, wherein said joint body has a top ceiling transversely extended to form a retraction surface to support said supporting platform, wherein said guiding joint further comprises a resilient element having one end operatively connected to said guiding end of said lifting arm, and another end biasing against said retraction surface of said joint body so as to normally exert a retracting force to restore said supporting platform in said operation position.

10. The installation arrangement, as recited in claim 6, wherein said joint body has a top ceiling transversely extended to form a retraction surface to support said supporting platform, wherein said guiding joint further comprises a resilient element having one end operatively connected to said guiding end of said lifting arm, and another end biasing against said retraction surface of said joint body so as to normally exert a retracting force to restore said supporting platform in said operation position.

11. The installation arrangement, as recited in claim 8, wherein said joint body has a top ceiling transversely extended to form a retraction surface to support said supporting platform, wherein said guiding joint further comprises a resilient element having one end operatively connected to said guiding end of said lifting arm, and another end biasing against said retraction surface of said joint body so as to normally exert a retracting force to restore said supporting platform in said operation position.

12. The installation arrangement, as recited in claim 2, wherein said supporting platform further has a standing leg upwardly and integrally extended from a side portion thereof, wherein when said supporting platform is inwardly flipped upside down to switch said position of said upper compartment below said lower compartment, said standing stand stands on said main casing to support said supporting platform in position with respect to said main casing.

13. The installation arrangement, as recited in claim 6, wherein said supporting platform further has a standing leg upwardly and integrally extended from a side portion thereof, wherein when said supporting platform is inwardly flipped upside down to switch said position of said upper compartment below said lower compartment, said standing stand stands on said main casing to support said supporting platform in position with respect to said main casing.

14. The installation arrangement, as recited in claim 11, wherein said supporting platform further has a standing leg upwardly and integrally extended from a side portion thereof, wherein when said supporting platform is inwardly flipped upside down to switch said position of said upper compartment below said lower compartment, said standing stand stands on said main casing to support said supporting platform in position with respect to said main casing.

15. The installation arrangement, as recited in claim 2, wherein said supporting platform comprises a supporting base forming said upper compartment above said supporting base and said lower compartment below said supporting base such that when said supporting platform is flipped in an upside down manner, said lower compartment is positioned above said upper compartment.

16. The installation arrangement, as recited in claim 8, wherein said supporting platform comprises a supporting base defining said upper compartment above said supporting base and said lower compartment below said supporting base such that when said supporting platform is flipped in an upside down manner, said lower compartment is positioned above said upper compartment.

17. The installation arrangement, as recited in claim 14, wherein said supporting platform comprises a supporting base forming said upper compartment above said supporting base and said lower compartment below said supporting base such that when said supporting platform is flipped in an upside down manner, said lower compartment is positioned above said upper compartment.

18. The installation arrangement, as recited in claim 1, wherein said supporting platform has a front installation opening communicating with said upper compartment of said supporting platform, wherein when said supporting platform is in said operation position, said front installation opening is arranged for aligning with a front opening of said main casing so as to communicate said front opening of said main casing with said upper compartment of said supporting platform.

19. The installation arrangement, as recited in claim 11, wherein said supporting platform has a front installation opening communicating with said upper compartment of said supporting platform, wherein when said supporting platform is in said operation position, said front installation opening is arranged for aligning with a front opening of said main casing so as to communicate said front opening of said main casing with said upper compartment of said supporting platform.

20. The installation arrangement, as recited in claim 17, wherein said supporting platform has a front installation opening communicating with said upper compartment of said supporting platform, wherein when said supporting platform is in said operation position, said front installation opening is arranged for aligning with a front opening of said main casing so as to communicate said front opening of said main casing with said upper compartment of said supporting platform.
